(19) United States
(12) Patent Application Publication
(10) Pub. No.: US 2015/0129914 A1
(43) Pub. Date: May 14, 2015

(54) LIGHT-EMITTING DIODE PACKAGE

(71) Applicant: LEXTAR ELECTRONICS CORPORATION, HSINCHU (TW)

(72) Inventor: Yun-Yi Tien, Hsinchu City (TW)

(21) Appl. No.: 14/340,491

(22) Filed: Jul. 24, 2014

(30) Foreign Application Priority Data
Nov. 8, 2013 (TW) 102140820

(51) Int. Cl. H01L 33/60; H01L 33/62; H01L 33/50

(52) U.S. Cl. CPC H01L 33/60; H01L 33/50; H01L 33/62
USPC 257/98

(57) ABSTRACT

The invention provides a light-emitting diode package. The light-emitting diode package includes a lead frame having a first lead and a second lead separated from each other by a space. A transparent plastic housing surrounds and encapsulates the lead frame to form a cup-shaped body having a recessed accommodating space. A bottom of the space is defined as a function area. The function area comprises an exposed surface of the first lead and an exposed surface of the second lead. A top of the space is defined as an opening for light emission. A light-emitting diode chip is mounted on the first lead in the function area, electrically connected to the second lead. A white reflective material is disposed on an isolation area in the function area, covering the first and second leads adjacent to the space. An encapsulation material fills the recessed accommodating space.

### CROSS REFERENCE TO RELATED APPLICATIONS

This Application claims priority of Taiwan Patent Application No. 102140820, filed on Nov. 8, 2013, the entirety of which is incorporated by reference herein.

### BACKGROUND OF THE INVENTION

1. Field of the Invention

The present invention relates to a method for fabricating a light-emitting diode (LED) package, and in particular it relates to a LED package having a wide light-emitting angle.

2. Description of the Related Art

Light emitting diodes (LEDs) have been widely applied in the illumination field due to advantages including high efficiency, longer lifespan, improved physical robustness, smaller size, and being environmentally friendly. Currently, the LED package used in LED tube lights usually belongs to the plastic leaded chip carrier (PLCC) package. However, the PLCC LED package has disadvantages including a narrow light-emitting angle. It is hard to reduce the number of the PLCC LED packages used in LED tube lights because of the mura effect problem. To solve the aforementioned problem, lenses are adopted to increase the light-emitting angle of the LED package. The conventional PLCC LED package with lenses, however, causes problems such as low light-emitting efficiency and high fabrication cost.

Thus, a novel LED package is desired.

### BRIEF SUMMARY OF THE INVENTION

A light-emitting diode package is provided. An exemplary embodiment of the light-emitting diode package includes a lead frame having a first lead and a second lead separated from each other by a space. A transparent plastic housing surrounds and encapsulates the lead frame to form a cup-shaped body having a recessed space. A bottom of the space is defined as a function area. The function area comprises an exposed surface of the first lead and an exposed surface of the second lead. The top of the space is defined as an opening for light emission. A light-emitting diode chip is mounted on the exposed surface of the first lead in the function area, electrically connected to the exposed surface of the second lead. A white reflective material is disposed on an isolation area in the function area, covering the exposed surfaces of the first and second leads adjacent to the space. An encapsulation material fills the recessed accommodating space.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIG. 1 is a plan view of one embodiment of a light-emitting diode package of the invention.

FIG. 2 is a cross-sectional view taken along the line A-A′ in FIG. 1.

### DETAILED DESCRIPTION OF THE INVENTION

The following description is of the contemplated mode of carrying out the invention. This description is made for the purpose of illustrating the general principles of the invention and should not be taken in a limiting sense. The scope of the invention is best determined by reference to the appended claims.

The present invention will be described with respect to embodiments and with reference to certain drawings, but the invention is not limited thereto and is only limited by the claims. The drawings described are only schematic and are non-limiting. In the drawings, the size of some of the elements may be exaggerated and not drawn to scale for illustrative purposes. The dimensions and the relative dimensions do not correspond to actual dimensions to practice the invention.

Embodiments provide a method for fabricating a light-emitting diode (LED) package. In some embodiments, the LED package includes a plastic leaded chip carrier (PLCC) package. A housing of the LED package is formed of transparent plastic materials. A light beam emitted from the LED chip can pass through the housing to the outside of the LED package, thereby increasing the light-emitting angle of the LED package. Additionally, a lead frame of the LED package, which is used to connect two electrodes of the LED chip, in accordance with some embodiments is covered by an additional white reflective material. The white reflective material can not only prevent the LED package from the light leakage problem, but also can increase the light-emitting efficiency and light-mixing efficiency of the LED package.

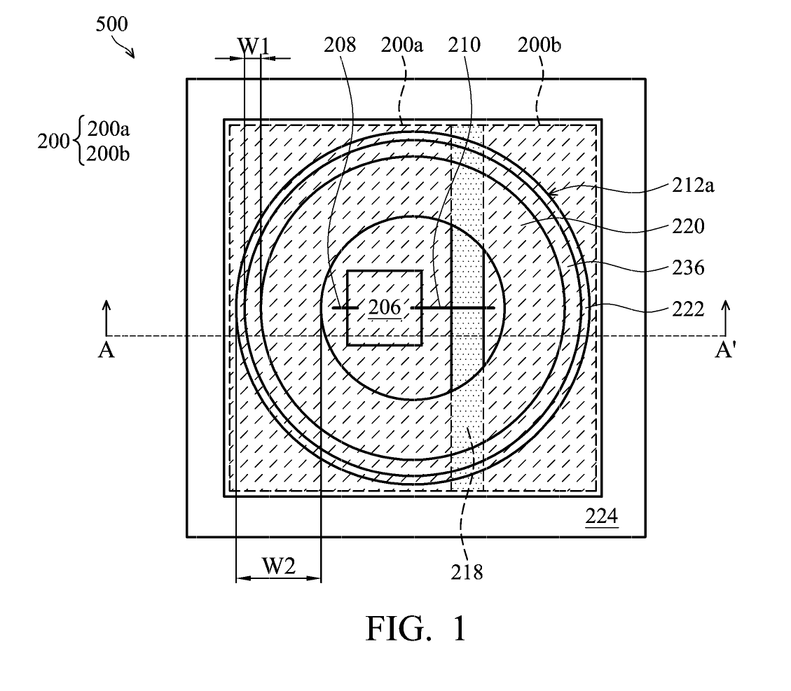

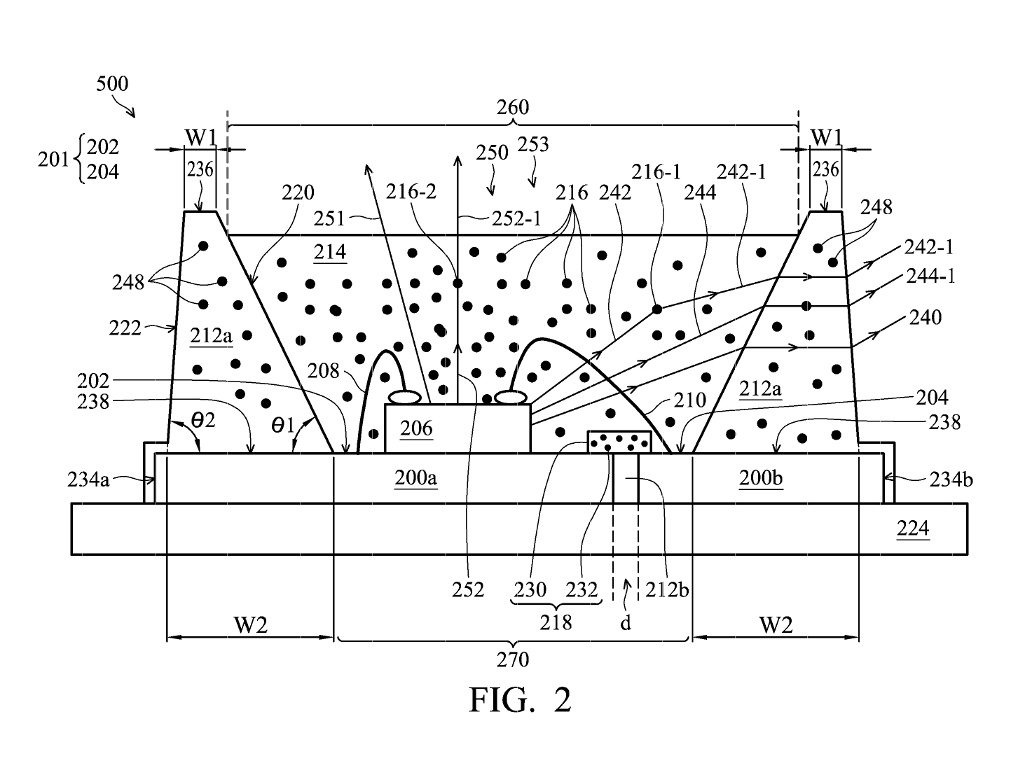

FIG. 1 is a plan view of one embodiment of a light-emitting diode (LED) package 500 of the invention. FIG. 2 is a cross-sectional view of the LED package 500. For the convenience of illustrating the internal arrangement of the LED, an encapsulation material and fluorescent powders dispersed in the encapsulation material are not shown in FIG. 1. Please refer to FIGS. 1 and 2, the LED package 500 includes a lead frame 200, a LED chip 206, a transparent plastic housing 212a, an encapsulation material 214 and a white reflective material 218. In one embodiment, the lead frame 200 is formed of metals. Also, the lead frame 200 has a first lead 200a and a second lead 200b separated from each other by a space d. In one embodiment, the space d is filled by an insulation spacer 212b. In one embodiment, a white paint is entirely coated on surfaces of the lead frame 200 to avoid light leakage.

As shown in FIGS. 1 and 2, in one embodiment, the transparent plastic housing 212a surrounds and encapsulates the lead frame 200 to form a cup-shaped body having a recessed accommodating space 250. A bottom of the recessed accommodating space 250 is defined as a function area 201. The function area 201 includes an exposed surface 202 of the first lead 200a and an exposed surface 204 of the second lead 200b. A top of the recessed accommodating space 250 is defined as an opening 253 for light emission. In one embodiment, an area 260 of the opening 253 for light emission is larger than an area 270 of the function area 201 in the plane view as shown in FIG. 1. Also, in one embodiment, the transparent plastic housing 212a encapsulates a sidewall 234a of the first lead 200a and a sidewall 234b of the second lead 200b. As shown in FIGS. 1 and 2, the LED chip 206 can be mounted on the exposed surface 202 of the first lead 200a in the function area 201 by an adhesive (not shown). The LED chip 206 can be electrically connected to the exposed surface 202 of the first lead 200a and the exposed surface 204 of the second lead 200b by the bonding wires 208 and 210, respectively. In one embodiment, the LED chip 206 is a blue light LED chip. The term “transparent” used to describe a feature refers to that the feature is allowed the light beam emitted from the LED chip to pass therethrough without being scattered. In one embodiment, because the transparent plastic housing 212a allows the light beam emitted from the LED chip 206 to pass therethrough, the light beam 240 emitted from the LED chip 206 and incident to the transparent plastic housing 212a can pass through the transparent plastic housing 212a to be incident to the outside of the LED package 500. In one embodiment, the transparent plastic housing 212a is formed of transparent plastic materials including silicon, epoxy, acrylate or combinations thereof. Also, the transparent plastic housing 212a and the insulation spacer 212b filling the space d are formed of the same materials. In one embodiment, the transparent plastic housing 212a can be formed by injecting the transparent plastic materials into the plastic molds already used in the fabrication process. Therefore, the goal of increasing the light-emitting angle of the LED package is achieved without additional cost foe the molds. In other embodiments, a plurality of other fluorescent powders 248 can be added within the transparent plastic housing 212a, and allowing the fluorescent powders 248 to be dispersed in the transparent plastic housing 212a. In one embodiment, the fluorescent powders 248 are yellow fluorescent powders.

In one embodiment, the transparent plastic housing 212a may have various designs in cross-sectional shapes to meet the requirements of various light-emitting angles. In one embodiment of the cross-sectional view as shown in FIG. 2, a top surface 236 of the transparent plastic housing 212a, which is away from the lead frame 200, has a first width W1. A bottom surface 238 of the transparent plastic housing 212a, which is close to the lead frame 200, has a second width W2 different from the first width W1. For example, in one embodiment as shown in FIG. 2, the transparent plastic housing 212a may be designed as a structure having a tapered cross-sectional view, widening from top to bottom. Therefore, the first width W1 of the top surface 236 is less than the second width W2 of the bottom surface 238 of the transparent plastic housing 212a. The angle θ1 between an inner-surface 220 and the bottom surface 238 and the angle θ2 between an outer-surface 222 and the bottom surface 238 of the transparent plastic housing 212a are both less than 90 degrees.

Alternatively, the transparent plastic housing 212a may be designed as a structure having a tapered cross-sectional view, widening from bottom to top. Therefore, the first width W1 of the top surface 236 is greater than the second width W2 of the bottom surface 238 of the transparent plastic housing 212a. The angle θ1 between the inner-surface surface 220 and the bottom surface 238 and the angle θ2 between the outer-surface 222 and the bottom surface 238 of the transparent plastic housing 212a are both less than 90 degrees.

Alternatively, the transparent plastic housing 212a may be designed as a structure having a fixed width in the cross-sectional view. Therefore, the first width W1 of the top surface 236 is equal to the second width W2 of the bottom surface 238 of the transparent plastic housing 212a. The angle θ1 between the inner-surface 220 and the bottom surface 238 and the angle θ2 between the outer-surface 222 and the bottom surface 238 of the transparent plastic housing 212a are both equal to 90 degrees. It should be noted that the transparent plastic housing 212a shown in FIG. 2 is illustrated merely as one embodiment of the invention. It is to be understood that the invention is not limited to the disclosed embodiments.

Please refer to FIG. 2 again. The LED package 500 further includes a white reflective material 218 to prevent the LED package 500 from light leakage. The white reflective material 218 is disposed on an isolation area (i.e. in the position of the space d) in the function area 201, covering the exposed surface 202 of the first lead 200a and the exposed surface 204 of the second lead 200b, which are adjacent to the space d. In one embodiment, the white reflective material 218 covers the insulation spacer 212b filling the space d. Therefore, the light beam emitted from the LED chip 206 and incident to the isolation area (i.e. in the position of the space d) can be blocked by the white reflective material 218, so that the light beam cannot pass through the insulation spacer 212b, which is formed by the transparent plastic materials. In one embodiment, the white reflective material 218 may include a plastic material 230. In one embodiment, the plastic material 230 may include silicon, epoxy, acrylate or combinations thereof. In one embodiment, the white reflective material 218 may further include a plurality of ceramic particles 232 dispersed in the plastic material 230. In one embodiment, a plurality of the ceramic particles 232 may be formed of BaSO₄, SiO₂, TiO₂ or combinations thereof

Please refer to FIG. 2 again, the LED package 500 further includes an encapsulation material 214 that fills the recessed accommodating space 250. Also, the encapsulation material 214 covers the LED chip 206, the bonding wires 208 and 210, and a portion of the lead frame 200. In one embodiment, the encapsulation material 214 may be may include silicon, epoxy, acrylate, silicone resins, or the like, or combinations thereof.

In one embodiment, a plurality of fluorescent powders 216 may be added to be dispersed in the encapsulation material 214. Therefore, a light beam 251 emitted from the LED chip 206 may directly pass through the encapsulation material 214 and incident through the opening 253 for light emission to the outside of the LED package 500. Alternatively, a light beam 252 emitted from the LED chip 206 may excite a fluorescent powder 216-2 to generate a secondary light beam 252-1. The secondary light beam 252-1 can pass through the encapsulation material 214 incident to the outside of the LED package 500 through the opening 253 for light emission. The transparent plastic housing 212a is “transparent” for the light beam emitted from the LED chip 206. A light beam 240 emitted from the LED chip 206 and incident to the transparent plastic housing 212a passes through the encapsulation material 214 and the transparent plastic housing 212a in sequence, incident to the outside of the LED package 500 through the transparent plastic housing 212a. Additionally, a light beam 242, which is emitted from the LED chip 206 incident to the transparent plastic housing 212a, may excite a fluorescent powder 216-1 to generate a secondary light beam 242-1. The secondary light beam 242-1 can pass through the encapsulation material 214 and incident to the outside of the LED package 500. From the aforementioned description, it can be seen that the transparent plastic housing 212a can further increase the light-emitting angle and light-mixing efficiency (the light beam emitted from the LED chip 206 and the secondary light beam excited from the fluorescent powders) of the LED package 500.

In some embodiments of the fluorescent powders 248 added within the transparent plastic housing 212a, a light beam 244, which is emitted from the LED chip 206 and incident to the transparent plastic housing 212a, may excite the fluorescent powder 248 to generate a secondary light beam 244-1. The secondary light beam 244-1 can pass through the transparent plastic housing 212a and incident to the outside of the LED package 500. From the aforementioned description, it can be seen that the transparent plastic housing 212a with the fluorescent powders 248 dispersed within can also further increase the light-emitting angle and light-mixing efficiency of the LED package 500.

In one embodiment, the materials for forming the encapsulation material 214 and the transparent plastic housing 212a can be chosen to form the LED package 500. For example, the materials for forming the encapsulation material 214 can be choose, so that the encapsulation material 214 has a first refractive index (n1). Also, the materials for forming the transparent plastic housing 212a can be chosen, so that the transparent plastic housing 212a has a second refractive index (n2). The first refractive index (n1) is designed to be larger than the second refractive index (n2), and the second refractive index (n2) is designed to be larger than the refractive index of the wafer. According to the design of the refractive indexes of the encapsulation material 214 and the transparent plastic housing 212a, the light beam, which is emitted from the LED chip 206 and passes through the encapsulation material 214 and incident upon the transparent plastic housing 212a, may have an incident angle and an exit angle relative to a normal line of an interface between the encapsulation material 214 and the transparent plastic housing 212a. The exit angle is greater than the incident angle. From the aforementioned description, it is to known that the design of the refractive indexes of the encapsulation material 214 and the transparent plastic housing 212a can also further increase the light-emitting angle of the LED package 500.

In some embodiments, the encapsulation material 214 can be designed according to the various designs of the transparent plastic housing 212a in cross-sectional shapes to meet the requirements of various light-emitting angles. For example, the encapsulation material 214, which is designed to have fluorescent powders dispersed within or have a specified refractive index, can be arranged with the transparent plastic housing 212a, which has a tapered cross-sectional view, widening from top to bottom or from bottom to top, or has a fixed width in a cross-sectional view, to achieve the specified light-emitting angle of the LED package 500.

In some other embodiments, the lead frame 200 can be bonded on a substrate 224. Also, the first lead 200a and the second lead 200b of the lead frame 200 may be electrically connected to the substrate 224, respectively.

In some embodiments, the substrate 224 may be a printed circuit board (PCB). In one embodiment, when the lead frame 200 is bonded on the substrate 224, the insulation spacer 212b filling the space d may also be electrically connected to the substrate 224.

Embodiments provide a light-emitting diode (LED) package, for example, a plastic leaded chip carrier (PLCC) package. Embodiments of the transparent plastic housing can be formed by injecting the transparent plastic materials into the plastic molds already used in the fabrication process. Therefore, the goals of increasing the light-emitting angle and light-mixing efficiency of the LED package are achieved. Additionally, one embodiment of the isolation area of the LED package, which connects to the two electrodes of the lead frame, may be covered by a white reflective material to prevent the LED package from the light leakage problem. Also, the light-emitting angle and light-mixing efficiency of the LED package are increased. Therefore, the LED package having a wide light-emitting angle can be fabricated using commonly used fabrication processes without requiring additional molds. In lighting applications such as tube lights, the LED package having a wide light-emitting angle may help to reduce the number of the LED packages used in a single lighting to achieve the improvement of the light-emitting efficiency, light-emitting angle and light-mixing efficiency of the LED package.

While the invention has been described by way of example and in terms of the embodiments, it is to be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A light-emitting diode package, comprising:
a lead frame having a first lead and a second lead separated from each other by a space;
a transparent plastic housing surrounding and encapsulating the lead frame to form a cup-shaped body having a recessed accommodating space, wherein a bottom of the space is defined as a function area, the function area comprises an exposed surface of the first lead and an exposed surface of the second lead, and a top of the space is defined as an opening for light emission;
a light-emitting diode chip mounted on the exposed surface of the first lead in the function area, electrically connected to the exposed surface of the second lead;
a white reflective material disposed on an isolation area in the function area, covering the exposed surfaces of the first and second leads adjacent to the space; and
an encapsulation material filling the recessed accommodating space.

2. The light-emitting diode package as claimed in claim 1, wherein the space is filled by an insulation spacer.

3. The light-emitting diode package as claimed in claim 2, wherein the transparent plastic housing and the insulation spacer are formed of the same materials.

4. The light-emitting diode package as claimed in claim 1, wherein the transparent plastic housing encapsulates sidewalls of the first and second leads.

5. The light-emitting diode package as claimed in claim 1, further comprising:
a plurality of fluorescent powders dispersed in the encapsulation material.

6. The light-emitting diode package as claimed in claim 1, further comprising:
a plurality of other fluorescent powders dispersed in the transparent plastic housing.

7. The light-emitting diode package as claimed in claim 1, wherein the encapsulation material has a first refractive index, and the transparent plastic housing has a second refractive index less than the first refractive index.

8. The light-emitting diode package as claimed in claim 7, wherein a first light beam, which is emitted from the light-emitting diode chip, and a second light beam, which is emitted from the fluorescent powders excited by the first light beam, pass through the opening for light emission or the transparent plastic housing to the outside of the light-emitting diode package.

9. The light-emitting diode package as claimed in claim 1, wherein an area of the opening for light emission is larger than that of the function area in a plan view.

10. The light-emitting diode package as claimed in claim 1, further comprising a substrate, wherein the lead frame is bonded on the substrate.

11. The light-emitting diode package as claimed in claim 1, wherein the white reflective material comprises a plastic material formed of materials comprising silicon, epoxy, acrylate or combinations thereof.

12. The light-emitting diode package as claimed in claim 11, further comprising:
a plurality of ceramic particles dispersed in the plastic material, wherein a plurality of the ceramic particles is formed of BaSO₄, SiO₂, TiO₂ or combinations thereof.
